(19) United States
(12) Patent Application Publication
(10) Pub. No.: US 2016/0126085 A1
(43) Pub. Date: May 5, 2016

(54) METHOD AND DEVICE FOR TREATING A SUBSTRATE SURFACE

(71) Applicant: EV GROUP E. THALLNER GMBH, St. Florian am Inn (AT)

(72) Inventors: Martin SCHMIDBAUER, Enzenkirchen (AT); Tobias ZENGER, Scharding (AT); Florian SCHMID, Ried im Innkreis (AT); Thomas WIESER, Kirchdorf am Inn (DE); Hermann STELZHAMMER, Andrichsfurt (AT); Martin TRACKSDORF, Neuburg am Inn (DE)

(73) Assignee: EV GROUP E. THALLNER GMBH, St. Florian am Inn (AT)

(21) Appl. No.: 14/896,065

(22) PCT Filed: Jul. 4, 2013
(86) PCT No.: PCT/EP2013/064151

§ 371 Date: Dec. 4, 2015

(51) Int. Cl. H01L 21/02; H01L 21/66; H01L 21/67

(52) U.S. Cl. CPC H01L 21/0206; H01L 21/67051; H01L 21/67103; H01L 21/67109; H01L 22/30; H01L 22/20

(57) ABSTRACT

A method for treatment of a substrate surface of a substrate by applying a liquid to the substrate surface, the liquid which has been applied to the substrate surface being heated by a heating area which is located above the substrate surface, wherein the temperature of the liquid is kept constant by moving the heating area up and down. Furthermore the invention relates to a corresponding device.

### FIELD OF THE INVENTION

The invention relates to a method and a device for treating a substrate surface.

### BACKGROUND OF THE INVENTION

In the semiconductor industry countless chemicals are used for processing of semiconductor substrates. Many of the chemicals have components which remain permanently on or in the substrate, other chemicals in turn are removed again from the surface of the substrate after use. One of the best known material classes which must be removed again after use is the photoresist.

Photoresists are used mainly for producing a surface mask. The resist is first applied to the surface of a substrate by a coating process. The most common types of application are spin resist coating and spray resist coating, The thickness of the resist layer is generally in the micrometer range. After application of the resist layer, very often a heat treatment step is carried out which allows the solvent to evaporate and leaves the clean, partially cured resist on the surface of the substrate. After this heat treatment step the resist can be exposed.

The removal of layers (cleaning), especially resist layers, takes place in special process units which can be roughly divided into two groups.

The first group of process units comprises so-called batch process units. In one batch process unit several wafers are fixed on a holding device and dipped into a bath. The bath consists of a chemical which is used for the process of stripping the coating. The batch process unit can be designed to be either hydrostatic or hydrodynamic. In the first version it is a batch with a standing, therefore noncirculating liquid. An advantage of this embodiment is that only very small amounts of chemicals are needed. The major disadvantage is the fouling of the chemical by the detached layer. In the course of the cleaning process the concentration of the components of the layer rises, Thus the cleaning efficiency drops at the same time. Furthermore the deposition rate of the layer components which have not been removed on the already cleaned wafers rises so that on average complete, high-purity surface cleaning of the substrates rarely takes place. The chemical can be changed after a certain number of processed wafers, the walls of the container in which the chemical is located however mostly remain contaminated. In the hydrodynamic version the chemical is continuously renewed and the layer components which have been stripped from the surface of the substrate are removed before re-contamination of the substrate surfaces or the walls of the container takes place at all. Batch process units therefore generally require large amounts of chemicals and therefore cause correspondingly high chemical costs. Furthermore the environment is unnecessarily burdened by large amounts of chemicals.

The second group of process units comprises so-called individual substrate process units which can also be called individual wafer process units when wafers are used. This type of unit allows only serial processing of substrates. At the start of the cleaning process, the chemical is applied to the layer, especially the resist, which is to be stripped or cleaned. The chemical remains for a certain time on the surface of the substrate, dissolves the layer and is afterwards removed in a controlled manner. The removal takes place preferably by spinning it off. The substrate is therefore preferably fixed on a substrate holder of a spin resist coater. The chemical is applied via spray nozzles or hoses.

Individual substrate process units heat the chemicals in exactly the same manner as batch process units. The temperature regulation of the chemicals is necessary to start and/or drive and/or accelerate a chemical reaction with the layer which is to be removed. The heat-up and/or cool-down rates, in exactly the same manner as the heating times and heating temperatures, are generally dependent on all the materials participating in the process, therefore on the layer and/or the chemical.

Individual substrate process units have several decisive advantages over batch process units. They consume many fewer chemicals, can remove the contaminated chemicals very easily from the system, require less energy supply since only a smaller amount of chemicals need be heated, and are thus generally for the most part cheaper, although the throughput of the wafers per unit of time is generally less. Furthermore it has been shown that the yield of correctly processed wafers in individual substrate process units is generally better than in batch process units.

Although the individual substrate process units therefore constitute a genuine alternative to batch process units, the controllable, exact and reproducible temperature regulation of the chemical constitutes a technical problem. In a batch process unit it is conversely very simple to produce a uniform temperature which can be adjusted and reproduced in a controlled manner since the chemical bath is large compared to the substrates which are to be treated.

In the individual substrate process units the small amount of the chemical which covers the surface of a substrate which is to be cleaned is sufficient to cause dissolution of the layer from the surface, but is not large enough to act as a heat buffer in the sense of statistical physics and thermodynamics. Furthermore the chemical in individual substrate process units wets only one side of the substrate, while the substrate in batch process units is completely surrounded by liquid and thus the substrate is optimally heated through.

But it has been shown in recent years that the constant maintenance of the temperature is of decisive importance for an efficient, complete, economical and reproducible cleaning process. It is not sufficient to heat the chemical above a certain critical temperature. The process window in which optimum cleaning takes place is very narrow and must be precisely maintained.

One technical problem is the heating which is generally one-sided so that there is a heat gradient which greatly influences the temperature of the liquid, especially the cleaning liquid.

### SUMMARY OF THE INVENTION

An object of the invention is to provide a method which is referenced especially to individual substrate process units and a device for treatment, especially cleaning of a substrate surface which is coated with a resist, in which the cleaning takes place more favorably and more promptly, especially also in a more environmentally-friendly manner.

This object is achieved with the features of the independent claim(s). Advantageous developments of the invention are given in the dependent claims. All combinations of at least two of the features given in the specification, the claims and/or the figures also fall within the scope of the invention. At the given value ranges, values within the indicated limits will also be considered to be disclosed as boundary values and will be claimed in any combination.

The invention describes a device and a method for keeping a liquid, preferably a chemical for treatment, especially cleaning of a surface, at a temperature as constant as possible and preferably at the same time for ensuring a temperature distribution which is as uniform as possible. Although an embodiment of the invention is used preferably for cleaning processes, the invention can be used for all processes in which a liquid must be kept at a constant temperature. Conceivable processes would be the following:

cleaning of a surface

temperature treatment of a temporary cement, preferably for evaporating the solvent developer process

wet chemical deposition of one component from the chemical on the substrate surface

electrochemical deposition

(wet chemical) etching process

self-organization process of molecules

lift-off process

The invention is used mainly for temperature regulation of chemicals which are used for stripping, therefore for removal of a layer, preferably a resist, from the surface of the substrates, especially wafers. Therefore the invention is based mainly on the idea of keeping constant the optimum temperature especially for stripping by a heater which is not dipped into the chemical, but which is located above the chemical in a controllable position.

The method of the invention and unit can be fundamentally used for the dedicated temperature regulation of each liquid. But preferably the temperature of a liquid layer is regulated whose thickness is small compared to its lateral diameter, especially with a ratio smaller than 1 to 10, preferably smaller than 1 to 100. The liquid can be any type of chemical, preferably a cleaning chemical. Preferably it is however a chemical for stripping of resists. Especially, the following chemicals can be used,

acetone

propylene glycol monomethylether acetate (PGMEA)

mesitylenes

series from the company MicroChemicals, AZ 100, TechniStrip P1316, TechniStrip NI555, TechniStrip NI105

DMSO and NMP

TMA

amines

ketones

Piranha Etch

acetonitrile

aniline

cyclohexane

n-pentane

triethylene glycol dimethylether (triglyme)

dimethyl acetamide

dimethyl formamide

dimethyl sulfoxide

1,4-dioxane

glacial acetic acid

acetic anhydride

ethyl acetate

ethanol

ethylene dichloride

ethylene glycol

anisole

benzene

benzonitrile

ethylene glycol dimethylether

petroleum ether/light gasoline

piperidine

propanol

propylene carbonate (4-methy-1,3-dioxo1-2-one)

pyridine

γ-butyrolactone

quinoline

chlorobenzene

chloroform

n-heptane

2-propanol (isopropyl alcohol)

methanol

3-methyl-1-butanol (isoamyl alcohol)

2-methyl-2-propanol (tert-butanol)

methylene chloride

methylethyl ketone (butanone)

N-methyl-2-pyrrolidone (NMP)

N-methyl formamide

tetrahydrofuran

ethyl lactate

toluene

dibutyl ether

diethylene glycol

diethyl ether

bromobenzene

1-butanol

tert-butylmethylether (TBME)

triethyl amine

triethylene glycol

formamide

n-hexane

nitrobenzene

nitromethane

1,1,1-trichloroethane

trichloroethene

carbon disulfide

sulfolan

tetrachloroethene

carbon tetrachloride

water

acids, in particular
H₂SO₃, H₂SO₄, HCL, H₃PO₄, HNO₃, H₂O₂, formic acid, acetic acid,

bases, in particular
NaOH, KOH, tetramethyl ammonium hydroxide (TMAH),

mixtures of the aforementioned chemicals.

A technical advantage of the invention includes the small amount of solvent which is used and which can be brought to a temperature in a controlled manner and whose temperature can be continuously monitored and if necessary can be regulated promptly enough to allow the solution process to proceed in a very limited, narrow process window. By correspondingly exact control/regulation of the cleaning temperature, especially at a constant heating surface temperature, very efficient and reproducible cleaning of the substrate surface which is to be cleaned takes place. Furthermore, with one embodiment of the invention a uniform temperature distribution which is therefore independent of the site is achieved. The temperature uniformity is important to ensure the uniform removal of the layer from the substrate.

One embodiment of the invention is comprised of a substrate holder and a heater which is located above and/or below the substrate holder, with a heating surface. The substrate holder is designed such that it can fix a substrate, preferably a wafer, more preferably a semiconductor wafer, most preferably a silicon wafer, and due to lateral bordering prevents a liquid which has been applied to the substrate from running off. The substrate holder is preferably built such that the fixed substrate forms the bottom for the added liquid and the bordering prevents the liquid from running off. The bordering with the substrate lying on the substrate holder forms a trough for accommodating the cleaning agent during cleaning. Reference is made especially to the disclosure of PCT/US2012/066204 for the construction.

The substrate holder is preferably located on a shaft which can be set into rotation around its axis. In this way the removal of the chemical after the completed cleaning step is enabled by spinning it off. Furthermore the rotation of the substrate holder during the cleaning process can be used to make the temperature uniform along the substrate surface and thus to more uniformly clean and remove the layer from the substrate surface. The temperature is most ideally made uniform at rotary speeds of the substrate holder as small as possible. The number of rounds per minute, rpm, is less than 3000, preferably less than 1000, more preferably less than 500, most preferably less than 100, most preferably of all less than 50, best between 30 and 0. Instead of rotation, a slight oscillation of the substrate holder around the shaft is conceivable. The substrate holder then carries out a torsional oscillation around the longitudinal axis of the shaft. The preferred torsional frequency here is below 100 Hz, preferably below 50 Hz, more preferably between 30 and 0 Hz. The chemical is preferably exposed to ultrasound in addition in order to develop a more efficient action. Mainly in the use of cleaning liquids can ultrasound have a primarily beneficial effect on the cleaning of the surface. Furthermore the cleaning time is reduced. The ultrasonic device is preferably installed directly in the substrate holder, but can also be moved over the liquid and immersed by a pivoting arm.

Preferably there is a heater over the substrate holder, with a heating surface which points toward the substrate. The heater is especially a large-area heater. The large-area heater has a heating area 0.1 times as large, preferably an equally large heating area, more preferably a heating area 1.5 times as large and most preferably a heating area twice as large as the substrate surface which is to be cleaned.

The shape of the large-area radiator is preferably congruent with the shape of the substrate. Since generally round substrates are used in the semiconductor industry, the heater therefore preferably has a circular shape. The shape of the heater can also be rectangular or adapted to the special shapes of the substrates. The heater is either a blanket heater or a zone heater. In a blanket heater only the temperature of the entire heating area can be set and changed. In a zone heater the temperature can be regulated for individual segments of the heater. The most preferred embodiment of a zone heater is comprised only of a central, centric, circular heating element and at least one annular, centered heating element which surrounds the central heating element. In one quite special embodiment the heater is shaped like a segment of a circle. In order to enable corresponding blanket temperature application to the chemical, relative rotation takes place between the chemical and the sample holder and the heating surface and the heater. This special shape of the heater is used mainly for compensation of locally different heat dissipation properties. Preferably in this special embodiment the heater moves so that the liquid does not experience any unnecessary fluctuation. The relative rotation between the chemical and the sample holder is most ideally reached at rotational speeds of the substrate holder which are as small as possible. The number of revolutions per minute here is less than 3000, preferably less than 1000, more preferably less than 500, most preferably less than 100, most preferably of all less than 10, best less than 1. In one quite special embodiment the sample holder and heater can be moved oppositely toward one another.

Preferably the heater is heated on the heating area to a heating temperature greater than 25° C., preferably greater than 100° C., more preferably greater than 200° C., most preferably greater than 300° C., most preferably of all greater than 400° C. The accuracy or deviation of the temperature regulation down or up here is especially better than 10° C., preferably better than 5° C., more preferably better than 1° C., most preferably better then 0.1° C., most preferably of all better than 0.01° C. In quite special embodiments the temperature of the liquid is always kept in the vicinity or even slightly above the flash point since the desired treatment, in particular the cleaning, can be carried out efficiently in this temperature range.

The heater is located at a distance to the substrate surface or to the surface of the liquid or cleaning liquid, especially the chemical, on the substrate which is to be cleaned. In particular during the cleaning process it can be necessary to change the distance of the heating area to the surface of the cleaning liquid so that the heater moves away from the liquid surface or approaches it. The preferred distance of the heater is less than 100 mm, preferably less than 50 mm, more preferably less than 25 mm, most preferably less than 10 mm, most preferably of all less than 1 mm.

In particular, for a certain application a spacing corridor is dictated which is preferably empirically determined and is filed in a control apparatus for control of the device and the process steps. Within the spacing corridor the heating area can be moved orthogonally to the substrate surface. The movement is carried out especially as a linear movement with corresponding drive means.

In a first preferred embodiment, sensors are integrated in the heater, using which the temperature of the liquid surface can be determined.

In a second, less preferred but conceivable embodiment the sensors are integrated in the sample holder under the substrate which is to be cleaned. The disadvantage of this embodiment is that the components which lie between the sensors which have been installed in the sample holder and the chemical can distort and adulterate the temperature since the heat can be partially lost via heat convection and heat radiation en route from the chemical to the sensors.

The calibration of the sensors by a calibration bath and a calibration substrate would be conceivable. Hereinafter, mainly the preferred first embodiment is described.

The accuracy of the sensors is especially better than 10° C., preferably better than 5° C., more preferably better than 1° C., most preferably better then 0.1° C., most preferably of all better than 0.01° C. Sensors can be preferably thermometers, bolometers, or pyrometers. The temperature is measured preferably without contact, in order to prevent contamination of the chemical with unwanted metals and to have to clean the temperature measuring device as rarely as possible. Measurement of the temperature by a temperature sensor which dips directly into the liquid would be conceivable. This sensor does not deliver locally resolved temperature data, but a very exact average temperature of the entire liquid. In one still more preferred embodiment several temperature sensors are mounted along the edge of the sample holder bordering the liquid at the level of the liquid volume and thus allow the temperature to be measured along the periphery of the liquid.

The heater can have more than one sensor and/or several types of sensors. Preferably there are several sensors, especially symmetrically distributed over the heater, most preferably in the form of a symmetrical pattern, on the heater, especially on the heating area. This enables in-situ recording of the temperature distribution of the liquid surface. If the use of several sensors is not possible or not desired, the sole sensor is preferably located in the center of the heater.

One aspect of the invention includes preheating the heater to a given temperature. The temperature is especially above the cleaning temperature since the amount of heat which has been produced on the heating area does not reach the liquid surface free of losses, but is partially lost. For very many applications the temperature of the heater is above the flash point of the chemical. After reaching the target temperature of the heater, the measurement of the temperature on the liquid surface begins. If the actual temperature is lower than the given setpoint temperature (liquid temperature), the distance between the heater and liquid surface is reduced. Moving the heater toward the liquid surface or moving the liquid surface toward the heater or heating area by raising the sample holder is conceivable. The first embodiment is preferred since the chemical is thus not moved in the z direction and thus has a quieter surface. Hereinafter, the preferred embodiment in which the heater is moved is always described.

Moving closer takes place by motor control depending on an algorithm of the closed loop. By the approach of the heating surface which is located especially on a heating plate to the liquid surface the distance which is to be bridged for the generated heat flow is reduced and thus at the same heat output less heat is lost between the heater and the liquid surface.

If the actual temperature is greater than the setpoint temperature, cooling takes place indirectly by the heater being moved away from the liquid surface by the closed loop, as a result of which a larger path to be bridged (distance between the heating area and liquid surface) for the heat flow arises. Due to the larger path, more heat is lost from the heat flow before the corresponding amount of heat arrives at the liquid surface. Due to the continuously progressing heat release of the liquid, of the substrate and of the entire device itself, therefore constant cooling takes place and in this way convergence of the actual temperature to the setpoint temperature occurs.

The motor for linear movement of the heater in the z direction (orthogonally to the heating area and/or the liquid surface and/or the substrate surface) and the sensor for determining the temperature of the liquid surface are connected to one another especially via a control circuit. The control circuit is preferably a software and/or hardware proportional integral differential controller (PID controller).

Another aspect of the invention is that neither the substrate or the substrate holder nor the heater need continuously change their temperature. A temperature change of a substrate holder and/or of a heater is accordingly cost-intensive, tedious and difficult to control. This applies mainly when the substrate holder and/or the heater have a high heat capacity and low thermal conductivity and thus the change of the temperature takes a correspondingly long time mainly when the temperature difference which is to be changed is large. Only the heater is kept at a constant temperature. To the extent the heater on the heating area has reached a given heating area temperature, the regulation of the liquid temperature takes place, especially exclusively, via the approach or movement of the heating area of the heater in the z direction. The heater is shifted by the PID controller and the measurement data of the temperature sensors in its z position such that the actual temperature is equal as well as possible to the setpoint temperature, the process temperature of the stripping.

Another aspect of the invention is that the heater need no longer dip into the chemical, therefore heats without contact. This solves several problems at the same time. First of all, a spontaneous or at least slow evaporation of the chemical by overheating can occur when a heater which has already been brought to temperature is immersed, or a heater which is cold and afterwards brought to temperature is immersed into the chemical. This is avoided in the present invention.

Secondly, the chemical and thus the surface of the substrate are not contaminated with the metals of the heater when the heater is not immersed. The heaters are especially coated with different metals which can dissolve in the chemicals and thus also contaminate the substrate surface before and/or during and/or after the action of the chemical on the layer which is to be removed; this can lead to serious problems when functional units such as for example microchips or memory chips are located there.

Thirdly, contamination of the surface of the heater by the chemical is at least largely prevented. Use of a heater which has been contaminated with a chemical moreover leads to an extremely nonuniform temperature distribution; this would accordingly have an adverse affect for the next batch to be cleaned. The nonuniform temperature distribution occurs mainly due to the fact that at correspondingly high temperatures the chemical can cure on the surface of the heater and forms a cured crust which is very difficult to remove. Since these impurities generally emerge irregularly on the surface of the heater, they also have a corresponding effect on the temperature distribution. The random distribution of the impurities causes the formation of a nonuniform temperature distribution since heat can be released from the heater at the sites of the impurities with greater difficulty.

Another aspect of the invention is that by applying the liquid on only one side of the substrate the opposite side of the substrate is not contaminated. Furthermore, by heating the heater only the region of the substrate near the surface, therefore the liquid layer, is thermally loaded, so that after spinning the liquid off and removing the substrate a new substrate can be immediately positioned on a substrate holder without having to wait beforehand for a tedious cooling process of the substrate holder and/or of the heater. If for example the chemical were heated above a heatable substrate holder, the entire substrate would be heated through. Moreover the next, still cold substrate could be damaged when loaded onto a hot substrate holder. Therefore before loading a new substrate the substrate holder would have to be cooled; this would be associated with energy, time and costs.

In an embodiment of the invention the warm or hot liquid is centrifuged off and the heater is moved into a safety position with a greater distance than during cleaning. Subsequently or at the same time the substrate which has been processed to completion is removed. A comparative cool, clean substrate holder for cleaning of the next substrate remains.

During substrate exchange or unloading and loading of a new substrate the heater can continue to be kept at the heating temperature so that heating can take place immediately after loading of the new substrate and applying a new liquid volume by the approach of the heater in fractions of seconds. Spontaneous evaporation of the chemical is prevented by temperature measurement via the temperature sensors in the heater during the approach and a correspondingly prematurely stopped heater.

Another idea of the invention is that the device of the invention can manage the different heat loss of the substrate holder and of the substrate. Thus different substrates with different thicknesses, different layers and different materials can be treated with the same unit.

In one special embodiment the heater is made as a segment heater. A segment heater is defined as a heater which has been divided into individual segments and with which the heating temperature can be locally triggered separately in each individual segment. Especially preferably in each segment there is at least one temperature sensor to be able to measure the temperature of the liquid surface directly under the corresponding segment and/or the heating temperature of the respective segment.

Here it can be provided that the segments of the heater are made rectangular in a plan view. In one alternative embodiment the segments are laid out annularly and each ring can be subdivided several times along its periphery. In another embodiment there are exactly two ring segments, one on the edge and one in the center. In one quite special embodiment the segments are made honeycombed, therefore hexagonal.

Preferably an embodiment of the invention has a safety device which prevents the immersion of the heater into the chemical. Here it can be a pin which reacts sensitively to the liquid and which is attached laterally to the heater and/or it can be an optical distance measuring apparatus and/or a current contact which is to be closed and which activates a fuse.

Although in embodiments of the invention there is no heater in the substrate holder, under certain circumstances it can be advantageous to install, in addition to the heater which is separate from the substrate holder, an additional heater directly into the substrate holder or to use only one heater which has been installed in the substrate holder. This heater would be important mainly for temperature uniformity, for preheating or maintaining the temperature. A substrate holder with an installed heater then has simply the disadvantage that cooling before reloading must take place to the extent the corresponding method of the invention requires such a cooled initial state. All considerations provided for the actual heater which is separate from the substrate holder with respect to the temperature sensors, segmenting, translational movement for active temperature regulation, etc. apply likewise to a heater which has been installed in the substrate holder. It must be especially watched that a heater which has been installed in or under the substrate holder can also be further designed such that it can execute translational movement on the substrate holder towards or away from the substrate holder. In this way, in turn the active temperature regulation of the liquid or of the entire substrate from the bottom is enabled not by the active heating and/or cooling of the heater, but by a movement of the heater onto the substrate or off the substrate. The most efficient embodiment would include a correspondingly thick hollow shaft in which a heater attached to a second lifting shaft can be moved within the hollow shaft toward the substrate or away from the substrate. Of course a heater could also be statically installed in a substrate sample holder.

The substrate to be treated is preferably completely covered by the liquid during the cleaning process.

The cleaning takes place preferably in an especially hermetically sealable cleaning chamber which can be evacuated and which is accessible by way of lifting a cover. The cleaning chamber can be evacuated to a pressure of less than 1 bar, preferably less than 1 mbar, more preferably less than 0.1 mbar, most preferably to less than 0.01 mbar, most preferably of all to less than 0.0001 mbar absolute pressure. Preferably this evacuation takes place before the liquid is added. A correspondingly low pressure would allow most liquids to boil at overly low temperatures. But the evacuation can remove undesirable gas components, mainly oxygen, from the chamber and prepare the chamber in this way for the flushing and filling with a desirable gas which is advantageous for the process, preferably an inert gas for flame and fire inhibition.

The cleaning chamber preferably has an exhaust gas control which can be controlled and programmed fully automatically. The volumetric flow of the exhaust gas line is between 1 m³/h and 1000 m³/h, preferably between 50 m³/h and 750 m³/h, most preferably between 100 m³/h and 500 m³/h, most preferably of all between 70 m³/h and 150 m³/h.

In one special embodiment it is possible to fill the cleaning chamber with gas via a valve. The cleaning chamber can then preferably also be exposed to overpressure. The pressure here is greater than or equal to 0.001 mbar, preferably greater than 0.1 mbar, more preferably greater than 1 mbar, most preferably greater than 1 bar, most preferably of all greater than 5 bar. Evacuation of the chamber (in particular to a pressure of less than 1 bar, preferably less than 1 mbar, more preferably less than 0.1 mbar, most preferably to less than 0.01 mbar, most preferably of all to less than 0.0001 mbar) after loading of the substrate to remove unwanted air components and a subsequent filling with a gas (in particular with the aforementioned parameters) which benefits the process of the invention are especially advantageous. They are preferably gases which reduce an ignition threshold of the chemical by their displacing or replacing the oxygen, and which preferably themselves cannot be oxidized or can only be oxidized with great difficulty. Examples of this would be nitrogen, helium, argon, and krypton. Gases with an especially low heat capacity and a high thermal conductivity would also be especially preferred. The lower the heat capacity, the smaller the amount of heat a gas can store per unit of temperature and the smaller the delay of the heat change should be on the chemical surface when the temperature change has been initiated on the heater. The system should therefore have thermal inertia as low as possible when using a gas with a heat capacity as low as possible. The specific heat capacity of the gas used should therefore be smaller than 10 J/(g*K), preferably smaller than 5 J/(g*K), more preferably smaller than 2 J/(g*K), still more preferably smaller than 1 J/(g*K), most preferably smaller than 0.5 J/(g*K), most preferably of all smaller than 0.1 J/(g*K). At the same time the heat should be transported as quickly as possible from the heater to the chemical. The thermal conductivity of the gas should be correspondingly large. The thermal conductivity should therefore be greater than 10⁻³ W/(m*K), preferably greater than 10⁻² W/(m*K), more preferably greater than 10⁻¹ W/(m*K), most preferably greater than 1 W/(m*K), most preferably of all greater than 10 W/(m*K), best greater than 100 W/(m*K). Gas mixtures comprised of an inert gas and a gas which is responsible for efficient thermal contact-making can also be especially preferably mixed.

The liquid is applied to the substrate holder via a hose and/or via nozzles after the substrate is mounted. When using nozzles preferably more than one nozzle, more preferably more than 5 nozzles, more preferably more than 10 nozzles, most preferably more than 50 nozzles are used for applying the liquid. Especially preferably the hose and/or the nozzles can also be located in the substrate holder so that a heater which has been moved very near the substrate holder does not inhibit the deposition of the chemical.

The liquid runs preferably over a heat exchanger before it is deposited on the surface of the substrate. In this way preheating of the liquid is already achieved. The heat source of the heat exchanger can be the exhaust heat of the heater and/or of the spun-off old liquid and/or electrical heating.

After spinning off the chemical from the surface of the substrate, cleaning can take place with a fresh chemical and/or with water.

At the end of the cleaning process the substrate can be cleaned with Dl water (deionized water) before removal. Cleaning takes place preferably via one or more nozzles.

The device of the invention according to one advantageous embodiment is equipped with an internal fire extinguishing system which has a fire alarm and/or at least one suction and/or one feed for flushing with inert gas. By using a fire extinguishing system, a chamber which can be evacuated and which can be filled with inert gas, and an actively controllable regulator it is thus especially simple to heat a liquid above its flash point without spontaneous ignition taking place. Thus, for the first time a unit is described which can keep a liquid above its flash point at temperature in a controlled manner without the liquid igniting.

A process of the invention for cleaning a surface of a substrate calls especially for one or more of the following steps, preferably in the following sequence:

loading of a substrate which is to be cleaned onto the substrate holder, especially with the formation of a trough for holding a (cleaning) liquid,

depositing the especially preheated (cleaning) liquid on the substrate surface,

approach of an especially preheated heating surface of a heater and continuous measurement of the heating temperature on the heating area and/or the cleaning temperature on the liquid surface,

keeping the heater at a preferred z position at a defined distance over the liquid surface in which it is ensured that the liquid surface has a desired cleaning temperature,

continuously measuring the temperature of the liquid surface and if necessary correspondingly readjusting the z position and the distance of the heater,

carrying out the cleaning process until the surface of the substrate is cleaned,

moving the heater into a safety position,

spinning the chemical off the substrate surface, especially over one edge of the trough, which edge is flattened with a ramp,

reflushing and cleaning of the substrate surface with DI water,

removing the processed substrate from the device.

Some steps of the indicated sequence need not be carried out. Furthermore it is conceivable for unnamed steps to be inserted into the aforementioned sequence. The parallel execution of several steps would also be conceivable.

The device of the invention is preferably part of a cluster system, more preferably part of a vacuum cluster system, still more preferably part of a high vacuum cluster system, most preferably of all part of an ultrahigh vacuum cluster system.

An embodiment of the invention can therefore be housed in a module which is separated via at least one load lock to a central chamber of the vacuum cluster. The separation of the atmosphere of the module in which the embodiment is located from the other modules, in particular from the central chamber of the vacuum cluster, can be controlled by the load lock.

The vacuum cluster can be evacuated to a pressure of less than 1 bar, preferably less than 10⁻³ mbar, more preferably less than 10⁻⁵ mbar, most preferably less than 10⁻⁸ mbar.

The module in which a device of the invention is located can preferably be evacuated to a pressure of less than 1 bar, preferably less than 10⁻³ mbar, more preferably less than 10⁻⁵ mbar, most preferably less than 10⁻⁸ mbar, preferably independently of the vacuum cluster.

If present and/or in the subsequent description of the figures features of the device are disclosed, they should also be considered disclosed as features of the method and vice versa.

### BRIEF DESCRIPTION OF THE DRAWINGS

Other features and embodiments of the invention will become apparent from the claims and the following description of the figures in the drawings.

FIG. 1 shows a schematic cross section of one embodiment of the invention,

FIG. 2a shows a schematic plan view of an inventive first embodiment of a heating area of the invention,

FIG. 2b shows a schematic plan view of an inventive second embodiment of a heating area of the invention,

FIG. 2c shows a schematic plan view of an inventive third embodiment of a heating area of the invention,

FIG. 2d shows a schematic plan view of an inventive fourth embodiment of a heating area of the invention,

FIG. 2e shows a schematic plan view of an inventive fifth embodiment of a heating area of the invention,

FIG. 2f shows a schematic plan view of an inventive sixth embodiment of a heating area of the invention, and

FIG. 3 shows a schematic of a cluster system of the invention with a device of the invention.

### DETAILED DESCRIPTION OF THE INVENTION

In the figures the same parts or parts with the same action are labeled with uniform reference numbers, the size ratios not being to scale, for the sake of illustration.

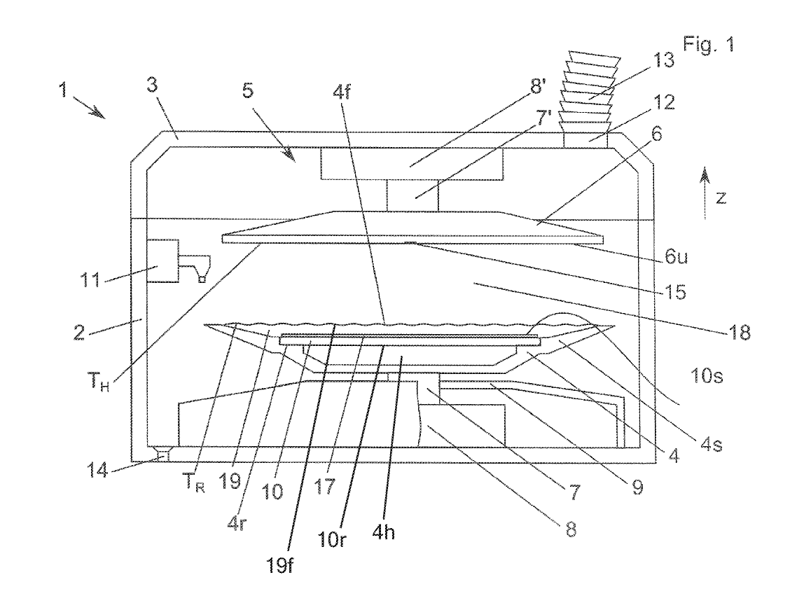

FIG. 1 shows one embodiment of a treatment module 1 of the invention. The treatment module 1 is comprised of a lower housing half 2 and an upper housing half 3. The housing halves 2, 3 are optional, but are preferably used especially as a sealable version. The upper housing half 3 is preferably made as a cover which can be removed or raised or tilted around a hinge, especially controlled by a control apparatus. The housing halves 2, 3 are preferably made hermetically tight so that an interior 18 can be evacuated or exposed to an overpressure to the atmosphere.

Within the lower housing half 2 there is a substrate holder 4. The substrate holder 4 is fixed especially on a lifting shaft 7. The lifting shaft 7 preferably allows not only the rotational movement of the substrate holder 4, but also its movement in the z direction in order to simplify the loading of a substrate 10. The lifting shaft 7 is controlled by a corresponding motor 8. The motor 8 can be covered with a protective jacket 9 in order to largely prevent contamination with a (cleaning) liquid 19 when the (cleaning) liquid 19 is spun off the substrate 10.

The embodiments of the substrate holder 4 which are conceivable preferably correspond to one of the embodiments of the patent application PCT/US2012/066204 to which reference is made in this regard. Fundamentally the substrate holder 4 should be designed such that the heat outflow via heat conduction is minimized and as much as possible only unilateral heating from the side of a heating apparatus 5 which is located above the substrate holder takes place. If a heater should also be attached underneath the substrate holder 4, the throughflow of heat via heat conduction is maximized.

The substrate holder 4 has in particular a trough shape with an especially annular shoulder 4r for holding the substrate 10 on its back 10r, preferably exclusively in a side edge region, an inner region of the substrate 10 being at least largely unsupported and being located above a trough cavity 4h.

The substrate 10 with a ring section 4s of the substrate holder forms an especially trough-shaped liquid receiver 4f. The latter is preferably sealed relative to the back 10r of the substrate.

A motor 8′ with a lifting shaft 7′ and a heater 6 of the heating apparatus 5 is located at least partially within the upper cover 3 and preferably fixed on it. The heater 6 is adjustable in the z direction via the lifting shaft 7′. The execution of the shaft as a lifting shaft 7′ also allows rotation of the heater 6; this can lead to a correspondingly better and mainly more uniform temperature distribution. The execution of the lifting shaft 7′ as a simple linear drive would also be conceivable, while a relative rotational movement between the heater 6 and the substrate holder 4 by the lifting shaft 7 takes place.

The heater 6 has a heating area 6u which is located opposite one substrate surface 10s and can be moved in one z direction toward the latter and away from it.

The interior 18 of the treatment module 1 can be evacuated via a suction opening 12. The introduction of a gas or gas mixture via the suction opening 12 and a suction line 13 which is connected to it are also conceivable. Accordingly, between the vacuum pump and the suction opening a valve (not shown) can be installed which after successful evacuation allows switching over to a gas source. An additional separate feed line which is independent of the suction line 13 or several feed lines to the interior 18 are also conceivable.

The substrate 10 with a layer 17 which is to be removed, especially a resist, is positioned and fixed on the substrate holder 4. Afterwards the deposition of a (cleaning) liquid 19 via a deposition system 11 takes place. The liquid 19 has preferably been preheated.

The heater 6 is heated to a heating temperature T_{H} on the heating area 6u. A temperature sensor 15 which is located on the heating area, especially in the center of the heating area 6u, or several temperature sensors measures/measure the heating temperature T on the heating area 6u and/or the cleaning temperature T_{R} of the liquid 19 on the liquid surface 19f and via a PID controller (not shown) controls the position of the heater 6 until the liquid 19 has the given cleaning temperature T_{R}.

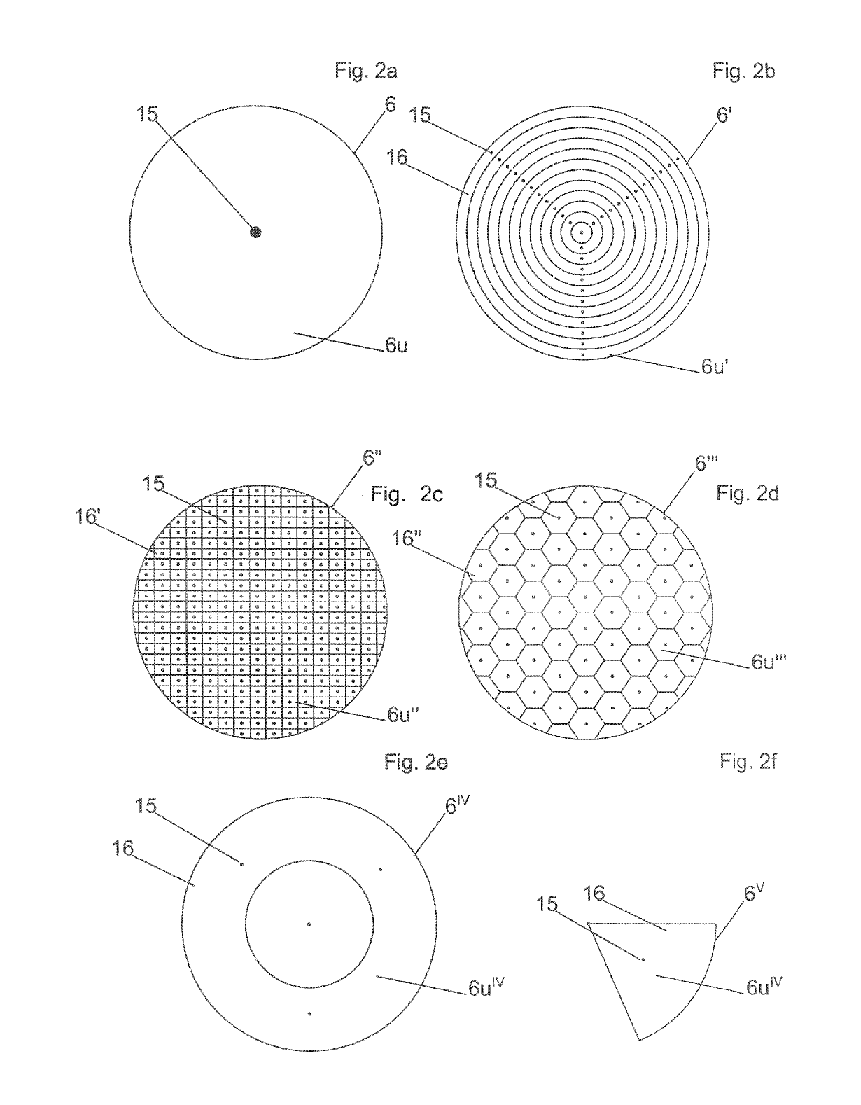

FIGS. 2a-f show several embodiments of heaters of the invention 6, 6′, 6″, 6″′, 6^{IV}, 6^{V}. The heating surfaces 6u, 6u′, 6u″, 6u″′, 6u^{IV}, 6u^{V} of six different heaters 6, 6′, 6″, 6′″, 6^{IV}, 6^{V} are shown.

In a first embodiment of the invention the heater 6 is comprised of a blanket heating area 6u, including an individual segment. The temperature sensor 15 is located in the center of the blanket heating area 6u.

In a second embodiment of the invention the heater 6′ is comprised of a heating area 6u′ which includes of segments 16′ of a circle. Each segment 16′ of the circle (except for the one in the center) has several, especially three, temperature sensors 15 which are located distributed on the periphery, especially uniformly, preferably each at an angular distance of 120°.

In a third embodiment of the invention the heater 6″ is comprised of rectangular segments 16′ in whose center there is one temperature sensor 15 at a time.

In a fourth embodiment of the invention the heater 6″′ is comprised of honeycombed hexagonal segments 16″ in whose center there is one temperature sensor 15 at a time.

In a fifth embodiment of the invention the heater 6^{IV} corresponds essentially to the second embodiment, only with fewer, especially exactly two circle segments 16.

In a sixth embodiment of the invention the heater 6^{V} is made as a circle sector 16″′ which can be turned especially around the center of the circle.

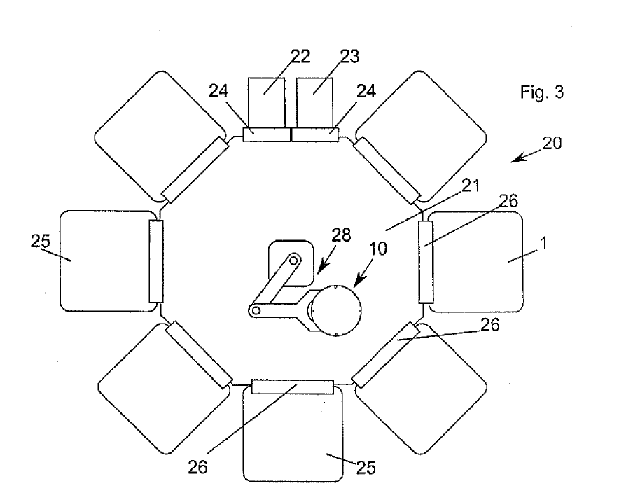

In one embodiment according to FIG. 3 the device of the invention is located as a treatment module 1 in a cluster system 20, more preferably part of a vacuum cluster system, still more preferably part of a high vacuum cluster system, most preferably of all part of an ultrahigh vacuum cluster system. The treatment module 1 can be separated, especially sealed, from a central chamber 21 of the cluster system 20 via at least one module load lock door 26. The separation of the atmosphere of the treatment module 1 from the other modules 25, especially from the central chamber 21, can be controlled by the module load lock door 26.

The cluster system can be evacuated to a pressure of less than 1 bar, preferably less than 10⁻³ mbar, more preferably less than 10⁻⁵ mbar, most preferably less than 10⁻⁸ mbar.

The treatment module 1, preferably independently of the pressure in the central chamber 21 or other modules 25, can be evacuated to a pressure of less than 1 bar, preferably less than 10⁻³ mbar, more preferably less than 10⁻⁵ mbar, most preferably less than 10⁻⁸ mbar.

Within the central chamber 21 a robot 28 transports the substrate 10 from one of the modules 25 to the treatment module 1. The substrate 10 travels first of all via a load lock 24 of a FOUP (Front Opening Unified Pod) 22 for the incoming substrates into the central chamber 21. After successful processing of the substrate 10 within the cluster system 20, the robot 28 deposits the substrate 10 via a FOUP load lock 24 in an outgoing FOUP 23.

### REFERENCE NUMBER LIST

1 treatment module

2 lower housing half

3 upper housing half

4 substrate holder

4r annular shoulder

4f liquid receiver

4s ring section

5 heating apparatus

6, 6′, 6″, 6″′, 6^{IV}, 6^{V} heater

6u, 6u′, 6u″, 6u′″, 6u^{IV}, 6u^{V} heating area

7, 7′ lifting shaft

8, 8′ motor

9 protective jacket

10 substrate

10s substrate surface

10r back

11 deposition system

12 suction opening

13 suction line

14 outflow

15 temperature sensor

16, 16′, 16″, 16′″ heating segment

17 layer

18 interior

19 liquid

19f liquid surface

20 cluster system

21 central chamber

22 input FOUP

23 output FOUP

24 load lock

25 modules

26 module load lock door

28 robot

1-10 (canceled)

11. A method for treatment of a substrate surface of a substrate, the method comprising:
applying a liquid to the substrate surface or to a layer which is present on the substrate surface, and
heating the liquid applied to the substrate surface with a heater having a heating area located above and/or below the substrate surface, wherein the heating area is moved up and down to keep the temperature T_{R} of the liquid constant.

12. The method as claimed in claim 11, wherein the method further comprises keeping a heating area temperature T_{H} of the heating area substantially constant at least during treatment of the substrate surface.

13. The method as claimed in claim 11, wherein the heating area is located parallel to the substrate surface during treatment of the substrate surface.

14. The method as claimed in claim 11, wherein a back of the substrate is held by a substrate holder, the back of the substrate surface facing away from the substrate surface.

15. The method as claimed in claim 11, wherein a distance of the heating area to a surface of said liquid is less than 100 mm.

16. The method as claimed in claim 11, wherein the method further comprises keeping the temperature T_{R} of the liquid substantially constant by control/adjustment of the movement of the heating area up and down.

17. The method as claimed in claim 11, wherein the method further comprises:
measuring the temperature T_{R} and/or the heating area temperature T_{H} at least during treatment of the substrate surface, by at use of least one temperature sensor attached to the heating area.

18. A device for treatment of a substrate surface of a substrate by applying a liquid to the substrate surface or to a layer which is present on the substrate surface, the device comprising:
a heater having a heating area located above and/or below the substrate surface for heating of the liquid which has been applied to the substrate surface, and
means for moving the heating area up and down to keep the temperature T_{R} of the liquid substantially constant.

19. The device as claimed in claim 18, wherein the device further comprises:
a rotatable substrate holder for holding a back of the substrate surface, the back of the substrate facing away from the substrate surface.

20. The device as claimed in claim 18, wherein the device further comprises:
at least one temperature sensor for measuring the temperature T_{R} and/or the heating area temperature T_{H}.

21. The method as claimed in claim 12, wherein the heating area temperature is kept constant during a changing of the substrate which is to be cleaned.

22. The method as claimed in claim 12, wherein the heating area temperature is kept constant during a preheating phase.

23. The method as claimed in claim 14, wherein said substrate holder is rotatable.

24. The method as claimed in claim 15, wherein the minimum distance of the heating area to the surface of said liquid is less than 1 mm.

25. The method as claimed in claim 16, wherein the temperature T_{R} of the liquid deviates less than 5° C.

26. The method as claimed in claim 25, wherein the temperature T_{R} of the liquid deviates less than 0.001° C.

27. The device as claimed in claim 20, wherein the at least one temperature sensor is attached to the heating area.
